(19) United States
(12) Patent Application Publication
(10) Pub. No.: US 2026/0198211 A1
(43) Pub. Date: Jul. 9, 2026

(54) DISPLAY DEVICE

(71) Applicant: SHARP DISPLAY TECHNOLOGY CORPORATION, Kameyama City, Mie (JP)

(72) Inventors: Masahiro HASEGAWA, Kameyama City Mie (JP); Akira SAKAI, Kameyama City Mie (JP)

(21) Appl. No.: 19/133,430

(22) PCT Filed: Dec. 9, 2022
(86) PCT No.: PCT/JP2022/045523

§ 371 Date: May 28, 2025

(51) Int. Cl. H10K 59/80; H10K 59/35

(52) U.S. Cl. CPC H10K 59/879; H10K 59/35; H10K 59/8722

(57) ABSTRACT

Mathematical relationships 165 nm≤3×CPL1+CPL2≤290 nm and 0.3×CPL1≤CPL2≤180 nm are satisfied where CPL1 is a thickness of a first cap layer and CPL2 is a thickness of a second cap layer.

### TECHNICAL FIELD

The disclosure relates to a display device.

### BACKGROUND ART

In a display device such as an organic light emitting diode (OLED) display device configured without using a circular polarizing plate, high luminance can be achieved, but a display quality may be decreased due to reflection of light in the display device. In the display device, by providing a light-absorbing member containing a black resin in the form of a partition provided between two light-emitting elements and/or so as to cover a backplane wiring line, the reflection of light can be suppressed, and thus the decrease in the display quality can be suppressed.

### CITATION LIST

### Patent Literature

PTL 1: JP 2001-332391 A

### SUMMARY

### Technical Problem

In the display device, since the reflection of light at an electrode layer on a light extraction side is not sufficiently suppressed, there is room for achieving a higher display quality.

### Solution to Problem

A display device according to an aspect of the disclosure includes a first light-emitting element including a light-emitting layer, and an electrode layer having a light-transmitting property and disposed above the light-emitting layer, a first cap layer disposed above the electrode layer, and a second cap layer disposed above the first cap layer and having a refractive index smaller than a refractive index of the first cap layer, in which mathematical relationships

$$165 nm \leq 3 \times CPL 1 + CPL 2 \leq 290 nm and \qquad ( 1 )$$

$$0.3 \times CPL 1 \leq CPL 2 \leq 180 nm \qquad ( 2 )$$

are satisfied where CPL1 is a thickness of the first cap layer and CPL2 is a thickness of the second cap layer.

### Advantageous Effects of Disclosure

According to an aspect of the disclosure, a display device having a high display quality can be achieved.

### BRIEF DESCRIPTION OF DRAWINGS

FIG. 1 is a cross-sectional view illustrating a schematic configuration of a display device according to a first embodiment of the disclosure.

FIG. 2 is a schematic view illustrating a display device according to a second embodiment of the disclosure.

FIG. 3 is a schematic view illustrating a configuration example of a colored layer.

FIG. 4 is a graph showing an example of light transmission characteristics of red light, green light, blue light, and a colored layer.

FIG. 5 is a schematic view of a display device according to a first comparative example.

FIG. 6 is a table showing materials, refractive indices, and thicknesses of a plurality of layers constituting a display portion of the display device according to the first comparative example.

FIG. 7 is a table showing information set in a simulation of characteristics related to reflection of light at an electrode layer with respect to a combination of a thickness of a first cap layer and a thickness of a second cap layer.

FIG. 8 is a table showing a reflectivity of light in the display device with respect to the combination of the thickness of the first cap layer and the thickness of the second cap layer.

FIG. 9 is a table showing a DCI-P3 coverage ratio in the display device with respect to the combination of thickness of the first cap layer and the second cap layer.

FIG. 10 is a table showing characteristics related to reflection of light at an electrode layer in a first comparative example, a second comparative example, a first example, a second example, a third example, and a fourth example.

### DESCRIPTION OF EMBODIMENTS

Embodiments for implementing the disclosure will be described. For convenience of description, members having the same functions as members described earlier may be denoted by the same reference numerals and signs, and the description thereof will not be repeated.

### First Embodiment

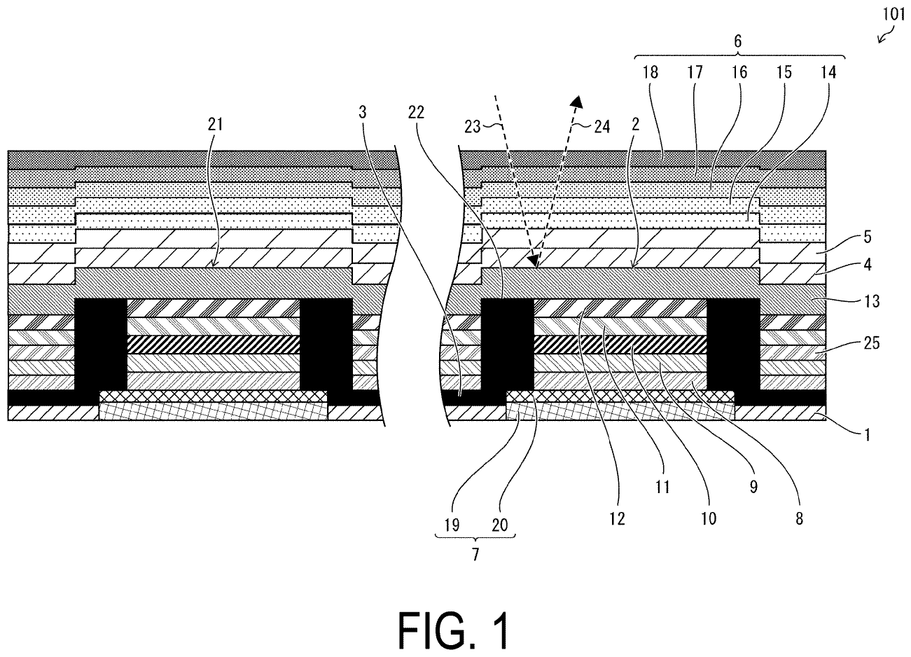

FIG. 1 is a cross-sectional view illustrating a schematic configuration of a display device 101 according to the present embodiment. Examples of the display device 101 include OLED display devices and quantum dot light emitting diode (QLED) display devices. The display device 101 includes a backplane wiring line 1, a first light-emitting element 2, a light-absorbing member 3, a first cap layer 4, a second cap layer 5, and a sealing layer 6.

The first light-emitting element 2 includes a first electrode layer 7, a hole injection layer 8, a hole transport layer 9, a light-emitting layer 10, an electron transport layer 11, an electron injection layer 12, and a second electrode layer (electrode layer) 13. The sealing layer 6 includes a first SiN layer 14, a SiON layer 15, a SiO layer 16, an organic matter layer 17, and a second SiN layer 18.

The backplane wiring line 1 is a wiring line provided on a backplane substrate. The first electrode layer 7 is provided on the backplane substrate. The backplane substrate is a substrate on which a TFT (thin film transistor), the backplane wiring line 1, the first electrode layer 7, and the like are provided at predetermined positions.

The first light-emitting element 2 is formed by layering the first electrode layer 7, the hole injection layer 8, the hole transport layer 9, the light-emitting layer 10, the electron transport layer 11, the electron injection layer 12, and the second electrode layer 13 in this order. The first light-emitting element 2 can emit light by the light-emitting layer 10 when a current flows between the first electrode layer 7 and the second electrode layer 13. The first light-emitting element 2 may be a self-light-emitting element. Examples of the first light-emitting element 2 include an OLED element and a QLED element.

In the disclosure, the refractive index is a refractive index with respect to light having a wavelength of 550 nm. A reflectivity and other various numerical values related to a luminous efficiency may be calculated by an organic device simulator “Setfos (trade name)”.

The first electrode layer 7 may have a layered structure of a silver layer 19 and an indium tin oxide (ITO) layer 20. The refractive index of the silver layer 19 may be 0.2+2.0i. The refractive index of the ITO layer 20 may be 2.00. The first electrode layer 7 may be an anode.

The hole injection layer 8 injects holes into the light-emitting layer 10. The refractive index of the hole injection layer 8 may be 1.80. The hole transport layer 9 transports holes to the light-emitting layer 10. The refractive index of the hole transport layer 9 may be 1.80. The electron transport layer 11 transports electrons to the light-emitting layer 10. The refractive index of the electron transport layer 11 may be 1.75. The electron injection layer 12 injects electrons into the light-emitting layer 10. The refractive index of the electron injection layer 12 may be 1.4. Each of the hole injection layer 8, the hole transport layer 9, the electron transport layer 11, and the electron injection layer 12 may be omitted from the display device 101 if desired.

The second electrode layer 13 has a light-transmitting property. The second electrode layer 13 is disposed above the light-emitting layer 10. The second electrode layer 13 may be made of an alloy of silver and magnesium. The thickness of the second electrode layer 13 may be 10 nm or more and 14 nm or less. The refractive index of the second electrode layer 13 may be 0.3+3.2i. The second electrode layer 13 may be a cathode.

The light-absorbing member 3 is disposed below the second electrode layer 13. The light-absorbing member 3 may include a partition 22 disposed between the first light-emitting element 2 and a second light-emitting element 21. The light-absorbing member 3 may cover the backplane wiring line 1. The light-absorbing member 3 may contain a colored resin, and examples the colored resin include a black resin. In the display device 101, since reflection of light can be suppressed by providing the light-absorbing member 3, a decrease in a display quality can be suppressed.

The first cap layer 4 is disposed above the second electrode layer 13. The first cap layer 4 may be provided on the second electrode layer 13. In other words, the first cap layer 4 may be formed directly on the second electrode layer 13. The first cap layer 4 may contain at least one of an aromatic amine compound and a spiro compound. Examples of the aromatic amine compound include 4,4′,4″-tris(carbazol-9-yl)-triphenylamine. Examples of the spiro compound include N,N′-bis(naphthalen-1-yl)-N,N′-bis(phenyl)-9,9′-spirobisfluorene. The first cap layer 4 may be made of an organic matter. The refractive index of the first cap layer 4 may be 1.90.

The second cap layer 5 is disposed above the first cap layer 4. The second cap layer 5 may be provided on the first cap layer 4. In other words, the second cap layer 5 may be formed directly on the first cap layer 4. The second cap layer 5 may contain at least one of LiF, MgF₂, AlF₃, and CaF₂. The second cap layer 5 may be made of an inorganic matter. The refractive index of the second cap layer 5 is smaller than the refractive index of the first cap layer 4. The refractive index of the second cap layer 5 may be 1.40.

The sealing layer 6 is formed by layering the first SiN layer 14, the SiON layer 15, the SiO layer 16, the organic matter layer 17, and the second SiN layer 18. in this order. The sealing layer 6 is disposed above the second cap layer 5. The sealing layer 6 seals at least the first light-emitting element 2. The refractive index of the first SiN layer 14 may be 1.80. The refractive index of the SiON layer 15 may be 1.76. The refractive index of the SiO layer 16 may be 1.46. The refractive index of the organic matter layer 17 may be 1.49. The refractive index of the second SiN layer 18 may be 1.80. The thickness of the first SiN layer 14 may be 1000 nm. The thickness of the SiON layer 15 may be 600 nm. The thickness of the SiO layer 16 may be 20 nm. The thickness of the organic matter layer 17 may be 10 μm. The thickness of the second SiN layer 18 may be 1000 nm.

The thickness of the first cap layer 4 is denoted by CPL1 and the thickness of the second cap layer 5 is denoted by CPL2. At this time, the display device 101 satisfies mathematical relationships (1) and (2). At this time, the display device 101 may satisfy mathematical relationships (3) and (4). At this time, the display device 101 may satisfy mathematical relationships (5) and (6). At this time, the display device 101 may satisfy mathematical relationships (7) and (8).

$$165 nm \leq 3 \times CPL + CPL 2 \leq 290 nm \qquad ( 1 )$$

$$0.3 \times CPL 1 \leq CPL 2 \leq 180 nm \qquad ( 2 )$$

$$195 nm \leq 3 \times CPL 1 + CPL 2 \leq 260 nm \qquad ( 3 )$$

$$0.9 \times CPL 1 \leq CPL 2 \leq 150 nm \qquad ( 4 )$$

$$240 nm \leq 3 \times CPL 1 + CPL 2 \leq 290 nm \qquad ( 5 )$$

$$0.4 \times CPL 1 \leq CPL 2 \leq 180 nm \qquad ( 6 )$$

$$240 nm \leq 3 \times CPL 1 + CPL 2 \leq 260 nm \qquad ( 7 )$$

$$0.9 \times CPL 1 \leq CPL 2 \leq 150 nm \qquad ( 8 )$$

According to the display device 101, since reflection of light at the second electrode layer 13 can be sufficiently suppressed, a display device having a high display quality can be achieved.

The first cap layer 4 and the second cap layer 5 may be configured such that first light 23 incident on the second cap layer 5 from an upper layer side of the second cap layer 5 and second light 24 obtained by reflection of the first light 23 by the second electrode layer 13 cancel each other out.

In the display device 101, a hole blocking layer 25 may be provided between the hole transport layer 9 and the electron transport layer 11 outside the first light-emitting element 2. The refractive index of the hole blocking layer 25 may be 1.85.

### Second Embodiment

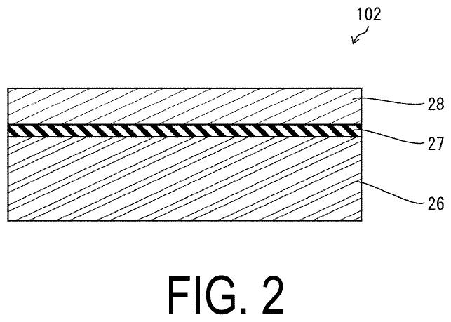

FIG. 2 is a schematic view of a display device 102 according to the present embodiment. The display device 102 includes a colored layer 28 in addition to a display portion 26 having the same structure as the display device 101. The colored layer 28 is disposed above the second cap layer 5 (see FIG. 1) provided in the display portion 26. The colored layer 28 may be bonded to the sealing layer 6 (see FIG. 1) provided in the display portion 26 by a first adhesive layer 27.

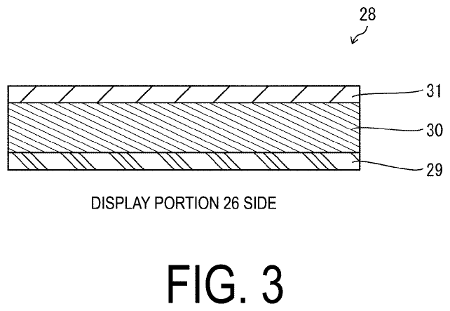

FIG. 3 is a schematic view illustrating a configuration example of the colored layer 28. The colored layer 28 may be formed by layering a visible light absorption layer 29, a base material 30, and an anti-reflection layer 31 in this order from the display portion 26 side. The reflectivity of the anti-reflection layer 31 may be 1.0%.

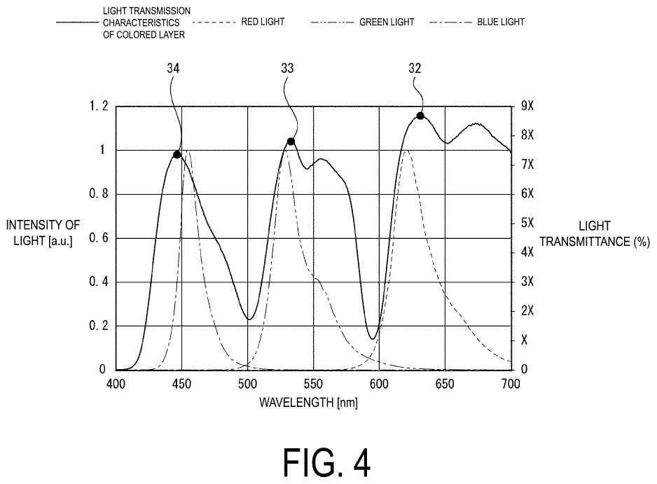

FIG. 4 is a graph showing an example of light transmission characteristics of red light (red light emitted by the light-emitting layer 10), green light (green light emitted by the light-emitting layer 10), blue light (blue light emitted by the light-emitting layer 10), and the colored layer 28. In FIG. 4, the horizontal axis represents the wavelength (unit: nm). The vertical axis in FIG. 4 represents a light intensity (arbitrary unit) for red light, green light, and blue light, and light transmittance (unit: %) for the light transmission characteristics of the colored layer 28. The colored layer 28 may have a peak 32 of light transmittance for red light emitted by the light-emitting layer 10, a peak 33 of light transmittance for green light emitted by the light-emitting layer 10, and a peak 34 of light transmittance for blue light emitted by the light-emitting layer 10.

For example, the visible light absorption layer 29 can be formed as outlined below. First, a commercially available visible light-absorbing material and an ultraviolet curable acrylic resin are mixed at a desired ratio to prepare a coating liquid. Subsequently, the coating liquid is applied to the base material 30 (for example, a triacetyl cellulose (TAC) film, a polyethylene terephthalate (PET) film, and a transparent polyimide film) with a bar coater or the like. Finally, the coating liquid applied to the base material 30 is irradiated with ultraviolet rays to cure the coating liquid applied to the base material 30.

The visible light-absorbing material may be a material suitable for absorbing light having a specific wavelength other than the peaks 32 to 34. In order to absorb light having wavelengths between the peak 33 and the peak 34, for example, “FDB-007” (maximum absorption wavelength: 495 nm) manufactured by Yamada Chemical Co., Ltd. may be used as the visible light-absorbing material. In order to absorb light having wavelengths between the peak 32 and the peak 33, for example, “FDG-007” (maximum absorption wavelength: 595 nm) manufactured by Yamada Chemical Co., Ltd. may be used as the visible light-absorbing material. In order to absorb light having wavelengths larger than the peak 32, for example, “FDR-005” (maximum absorption wavelength: 735 nm) manufactured by Yamada Chemical Co., Ltd. may be used as the visible light-absorbing material.

### EXAMPLES

### First Comparative Example

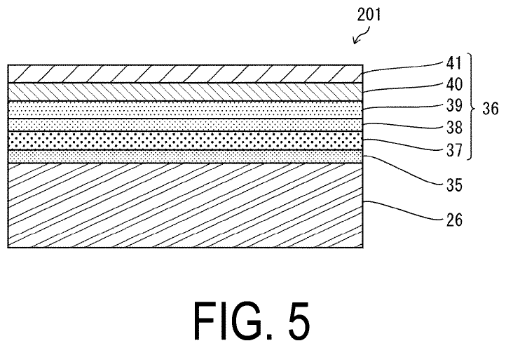

FIG. 5 is a schematic view of a display device 201 according to a first comparative example. The display device 201 includes the display portion 26 and a circular polarizing plate 36. In the display device 201, the sealing layer 6 (see FIG. 1) provided in the display portion 26 and the circular polarizing plate 36 may be bonded to each other by the second adhesive layer 35.

The circular polarizing plate 36 may be a commercially available circular polarizing plate. For example, the circular polarizing plate 36 includes a retardation film (λ/4 plate) 37, a polarizer 39, and a support film 41. The retardation film 37 and the polarizer 39 may be bonded to each other by a third adhesive layer 38. The polarizer 39 and the support film 41 may be bonded to each other by an adhesive layer 40. The support film 41 may support the retardation film 37 and the polarizer 39 and have a moisture-proof function.

A slow axis of the retardation film 37 and an absorption axis of the polarizer 39 may form an angle of 45°. The retardation film 37 may exhibit reverse wavelength dispersion characteristics in which a phase difference value increases according to the wavelength of measurement light. As the retardation film 37 exhibiting the reverse wavelength dispersion characteristics, a polycarbonate film “PURE-ACE (trade name)” manufactured by TEIJIN LIMITED. or the like may be used. The polarizer 39 can be formed by immersing polyvinyl alcohol (PVA) in an iodine aqueous solution and perform uniaxially stretching.

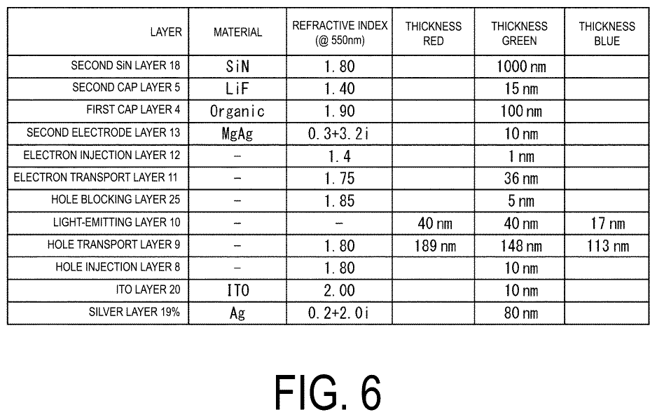

FIG. 6 is a table showing materials, refractive indices, and thicknesses of a plurality of layers constituting the display portion 26 of the display device 201 according to the first comparative example. The notations Red, Green and Blue mean the followings, respectively.
Red: a case where the first light-emitting element 2 emits red light (red pixel)
Green: a case where the first light-emitting element 2 emits green light (green pixel)
Blue: a case where the first light-emitting element 2 emits blue light (blue pixel)

### Second Comparative Example

A second comparative example is obtained by omitting the second adhesive layer 35 and the circular polarizing plate 36 from the first comparative example, and can be interpreted as the display device 101. CPL1 and CPL2 of the second comparative example are the same as CPL1 and CPL2 of the first comparative example, respectively. That is, in the second comparative example, CPL1=100 nm and CPL2=15 nm.

### First Example

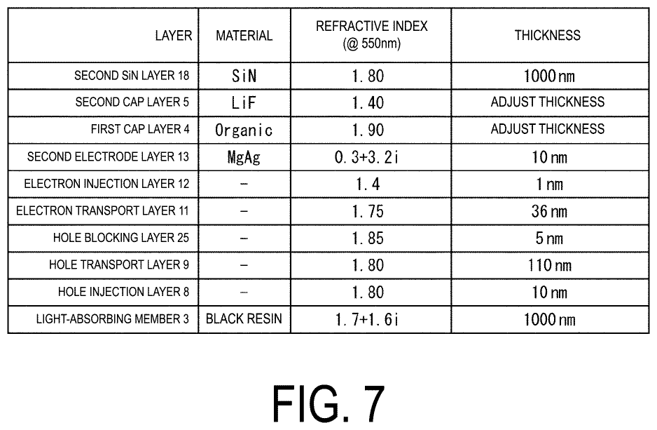

Based on the second comparative example, a simulation of characteristics related to reflection of light at the second electrode layer 13 was performed with respect to a combination of CPL1 and CPL2. FIG. 7 is a table showing information set in the simulation.

The refractive index of the layers above the sealing layer 6 was 1.5. In consideration of an area in a plan view, information on a common layer (a layer applied in solid) was used. On the assumption that the first electrode layer 7 was covered with the light-absorbing member 3, information of the light-absorbing member 3 was used instead of information of the first electrode layer 7.

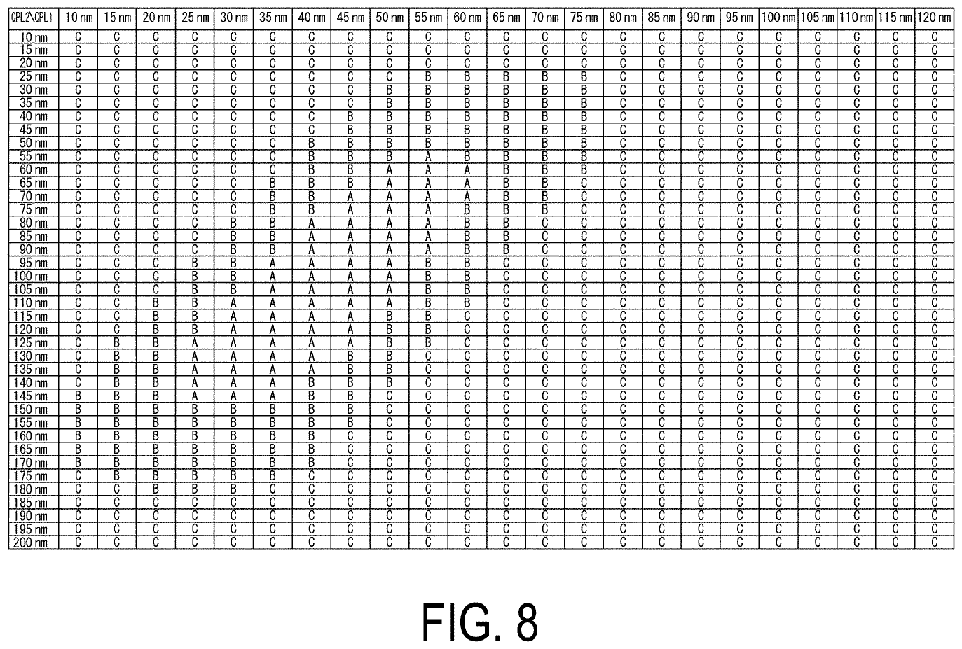

FIG. 8 is a table showing the reflectivity of light in the display device 101 with respect to the combination of CPL1 and CPL2. In FIG. 8, each value of CPL1 is shown in the horizontal direction and each value of CPL2 is shown in the vertical direction. In FIG. 8, determination results of the reflectivity are expressed in three stages of A, B, and C. The definitions of A, B and C are as follows, respectively.
A: less than 10%
B: 10% or more and less than 15%
C: 15% or more

A condition that the mathematical relationships (1) and (2) are satisfied can be interpreted as the combination of CPL1 and CPL2 in which the determination of A or the determination of B is obtained is approximated by the mathematical relationships. A condition that the mathematical relationships (3) and (4) are satisfied can be interpreted as the combination of CPL1 and CPL2 in which the determination of A is obtained is approximated by the mathematical relationships.

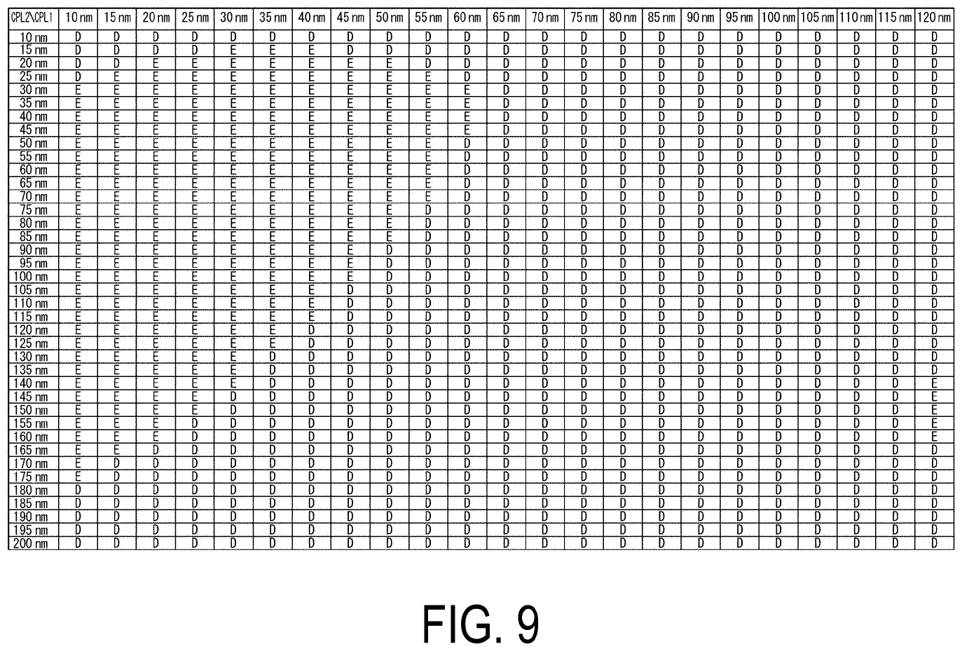

FIG. 9 is a table showing a DCI-P3 coverage ratio in the display device 101 with respect to the combination of CPL1 and CPL2. In FIG. 9, each value of CPL1 is shown in the horizontal direction and each value of CPL2 is shown in the vertical direction. In FIG. 9, the determination results of the DCI-P3 coverage ratio are represented by two stages of D and E. The definitions of D and E are as follows, respectively.
D: greater than 98%
E: 98% or less

A condition that the mathematical relationships (5) and (6) are satisfied can be interpreted as the combination of CPL1 and CPL2 in which both the determination of A or the determination of B and the determination of D are obtained is approximated by the mathematical relationships. A condition that the mathematical relationships (7) and (8) are satisfied can be interpreted as the combination of CPL1 and CPL2 in which both the determination of A and the determination of D are obtained is approximated by the mathematical relationships.

In the above-described second comparative example (CPL1=100 nm, CPL2=15 nm), the reflectivity of light in the display device 101 is determined to be C, and thus the reflectivity is high and the display quality is low.

In a first example, CPL1=60 nm and CPL2=60 nm. The configurations other than CPL1 and CPL2 are the same between the first example and the second comparative example. In the first example, the reflectivity of light in the display device 101 is determined to be A. It can be seen that the first example has a low reflectivity and a high display quality as compared with the second comparative example.

### Second Example

In the second example, the thickness of the hole transport layer 9 and the thickness of the electron transport layer 11 are changed from those in the first example. In the second example, the thickness of the hole transport layer 9 is any of 189 nm (Red), 150 nm (Green), and 117 nm (Blue), and the thickness of the electron transport layer 11 is 46 nm. The configurations other than the thickness of the hole transport layer 9 and the thickness of the electron transport layer 11 are the same between the second example and the first example.

In the second example, the thicknesses of the hole transport layer 9 and the electron transport layer 11 are optimized so as to obtain a larger microcavity effect than that in the first example.

### Third Example

In the third example, the first adhesive layer 27 and the colored layer 28 are added to the second example (in other words, although the second example is the display device 101, the third example is the display device 102).

### Fourth Example

A fourth example is different from the third example in that a high refractive index adhesive is used as the first adhesive layer 27. The high refractive index adhesive is used to buffer the difference between the refractive index (1.80) of the second SiN layer 18 provided in the display portion 26 and the refractive index (example: 1.50) of the colored layer 28. For example, a high refractive index adhesive “Lumiplus LPK series” (refractive index: from 1.62 to 1.65) manufactured by MITSUBISHI GAS CHEMICAL COMPANY, INC. may be used as the high refractive index adhesive.

### SUMMARY

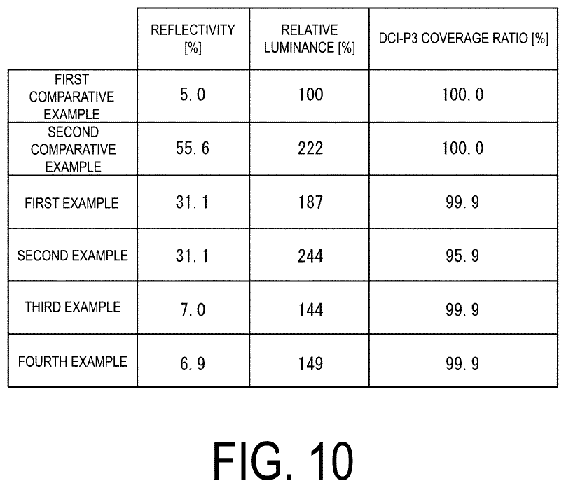

FIG. 10 is a table showing characteristics related to reflection of light in the second electrode layer 13 in the first comparative example, the second comparative example, the first example, the second example, the third example, and the fourth example. The characteristics include a reflectivity of light in the display device (hereinafter simply referred to as a reflectivity), relative luminance of the display device (hereinafter simply referred to as a relative luminance), and the DCI-P3 coverage ratio in the display device (hereinafter simply referred to as a DCI-P3 coverage ratio). The relative luminance indicates luminance (unit: %) when the luminance of the first comparative example is 100%.

According to FIG. 10, the followings (A) to (D) can be seen.
(A) The first example has a low reflectivity and also has low relative luminance as compared with the second comparative example.
(B) The second example has high relative luminance but has a low DCI-P3 coverage ratio as compared with the first example.
(C) The third example and the fourth example have a low reflectivity as compared with the second comparative example and a high DCI-P3 coverage ratio as compared with the second comparative example.
(D) The fourth example has a low reflectivity and high relative luminance as compared with the third example.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A display device comprising:
a first light-emitting element including
a light-emitting layer, and
an electrode layer having a light-transmitting property and disposed above the light-emitting layer;
a first cap layer disposed above the electrode layer; and
a second cap layer disposed above the first cap layer and having a refractive index smaller than a refractive index of the first cap layer,
wherein mathematical relationships
$$165 nm \leq 3 \times CPL 1 + CPL 2 \leq 290 nm and \qquad ( 1 )$$
$$0.3 \times CPL 1 \leq CPL 2 \leq 180 nm \qquad ( 2 )$$
are satisfied where CPL1 is a thickness of the first cap layer and CPL2 is a thickness of the second cap layer.

2. The display device according to claim 1,
wherein mathematical relationships
$$195 nm \leq 3 \times CPL 1 + CPL 2 \leq 260 nm and \qquad ( 3 )$$
$$0.9 \times CPL 1 \leq CPL 2 \leq 150 nm \qquad ( 4 )$$
are satisfied.

3. The display device according to claim 1,
wherein mathematical relationships
$$240 nm \leq 3 \times CPL 1 + CPL 2 \leq 290 nm and \qquad ( 5 )$$
$$0.4 \times CPL 1 \leq CPL 2 \leq 180 nm \qquad ( 6 )$$
are satisfied.

4. The display device according to claim 1,
wherein mathematical relationships
$$240 nm \leq 3 \times CPL 1 + CPL 2 \leq 260 nm and \qquad ( 7 )$$
$$0.9 \times CPL 1 \leq CPL 2 \leq 150 nm \qquad ( 8 )$$
are satisfied.

5. The display device according to claim 1, further comprising:
a colored layer disposed above the second cap layer and having a peak of light transmittance for red light emitted by the light-emitting layer, a peak of light transmittance for green light emitted by the light-emitting layer, and a peak of light transmittance for blue light emitted by the light-emitting layer.

6. The display device according to claim 1, further comprising:
a light-absorbing member disposed below the electrode layer.

7. The display device according to claim 6,
wherein the light-absorbing member includes a partition disposed between the first light-emitting element and the second light-emitting element.

8. The display device according to claim 6,
wherein the light-absorbing member includes a colored resin.

9. The display device according to claim 1,
wherein the electrode layer is made of an alloy of silver and magnesium and has a thickness of 10 nm or more and 14 nm or less.

10. The display device according to claim 9,
wherein the electrode layer is a cathode.

11. The display device according to claim 1,
wherein the first cap layer includes at least one of an aromatic amine compound and a spiro compound.

12. The display device according to claim 1,
wherein the first cap layer is made of an organic matter.

13. The display device according to claim 1,
wherein the first cap layer is provided on the electrode layer.

14. The display device according to claim 1,
wherein the second cap layer includes at least one of LiF, MgF₂, AlF₃, and CaF₂.

15. The display device according to claim 1,
wherein the second cap layer is made of an inorganic matter.

16. The display device according to claim 1,
wherein the second cap layer is provided on the first cap layer.

17. The display device according to claim 1,
wherein the first cap layer and the second cap layer are configured in a manner that first light incident on the second cap layer from an upper layer side of the second cap layer and second light obtained by reflection of the first light by the electrode layer cancel each other out.

18. The display device according to claim 1, further comprising:
a sealing layer disposed above the second cap layer and sealing at least the first light-emitting element.

19. The display device according to claim 1,
wherein the first light-emitting element is a self-light-emitting element.
